(19) United States
(12) Patent Application Publication
(10) Pub. No.: US 2009/0294993 A1
(43) Pub. Date: Dec. 3, 2009

(54) Packaging substrate structure

(75) Inventor: Shih-Ping Hsu, Hsin-feng (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/153,914

(22) Filed: May 28, 2008

(51) Int. Cl. H01L 23/52

(52) U.S. Cl. 257/779; 257/E23.141

(57) ABSTRACT

A packaging substrate structure is disclosed, which comprises a dielectric material with Young's Modulus less than 1 Gpa and moisture absorption ratio less than 1.0% in a solder mask, an outer dielectric layer or the combination. The package substrate structure improves the stability and the integration of the product.

### BACKGROUND OF THE INVENTION

1. Field of the Invention

The present invention relates to a packaging substrate structure, and, more particularly, to a packaging substrate structure comprising a dielectric material with Young's Modulus less than 1 GPa and moisture absorption ratio less than 1.0%.

2. Description of Related Art

Customer demands of the electronics industry continue to evolve rapidly, and the main trends of electronic devices focus on high integration and miniaturization. Moreover, in order to satisfy those requirements, especially in the packaging of semiconductor devices, development of circuit boards with the maximum amount of active and passive components and conductive wires has transferred from single-layered boards to multiple-layered boards. This means that a greater usable area on circuit board is available due to interlayer connection technology.

In general, a conventional semiconductor packaging structure is made in a way that a semiconductor chip is mounted on the top surface of the substrate. Then the combined substrate is processed in wire bonding or flip chip to electrically connect the semiconductor chip with the top surface of the substrate, and solder balls are disposed on the bottom surface of the substrate to provide electrical connections for an external electronic device such as a printed circuit board. The advantage of the flip chip, compared with wire bonding, is that the electrical connection between the semiconductor chip and the circuit board is achieved through the solder bumps but not through the gold bonding wires, so that the integration of the semiconductor packaging structure may be improved because the size of the semiconductor packaging substrate can be reduced. Meanwhile, the electrical characteristics may be improved without using metal wires, and the demands for the semiconductor device with high density and high speed may be satisfied.

The manufacturing of conventional packaging substrate structures are started from a core substrate, followed by drilling, plating metal in through holes, plugging holes, patterning circuits, etc., to complete inner circuit structures. Subsequently, as shown in FIG. 1A, the multilayer carrier, which has a built-up structure thereon, is formed by the built-up technology. First, a core substrate 11, of which built-up structures 12 are respectively disposed on two sides, is provided. Besides, the circuit layers on the two sides of the core substrate 11 are electrically connected by a plated through hole 111. The built-up structures 12 respectively comprise a dielectric layer 121, an upper circuit layer 122 laminated on the dielectric layer 121, and conductive vias 123 stacked in the dielectric layer 121. Furthermore, plural conductive pads 124 are formed on the surfaces of the built-up structures 12, and a solder mask 12, having plural openings 131 located thereon to expose the conductive pads 124, is formed on the outer surfaces of the built-up structure 12. Moreover, solder materials (not shown in FIG. 1) are formed in the openings 131 so that the packaging substrate structure can be electrically connected to the outer electronic components.

Generally, the dielectric layer 121 is made of a photosensitive or non-photosensitive material, such as Ajinomoto Build-up film (ABF), poly(phenylene ether) (PPE), poly(tetra-fluoroethylene) (PTFE), FR4, FR5, liquid crystal polymer (LCP), benzocylobutene (BCB), polyimide (PI), aramide, and bismaleimide triazine (BT), or a mixture of epoxy resin and glass fiber. The solder mask is made of green lacquer and the like. Nevertheless, built-up structures contain at least three layers, which are formed on multilayer substrates with a high number of input/output pins. Moreover, stacked conductive via structures are often used in the multilayer substrate, too. The dielectric layer 121 and the solder mask 13 are respectively made of a material having Young's modulus or elastic modulus greater than 3 Gpa. Besides, the coefficient of thermal expansion (CTE) thereof is about 40 ppm/° C. while the temperature is lower than the glass transition temperature, and is about 140 ppm/° C. while the temperature is greater than the glass transition temperature. The moisture absorption ratio thereof is greater than 1.0% so that it is easy to absorb moisture. The material having the aforementioned properties can be applied in packaging substrates, due to high compatibility to the stability requirement of standard reliability test and wide acceptance by clients. However, the Young's modulus and the moisture absorption ratio of the used material are too great, so it is difficult to apply this material to the packaging substrate with a high number of I/O pins. Furthermore, while chips are mounted on packaging substrates, the instability of products, resulted from the mismatch of coefficient of thermal expansion, causes the “popcorn phenomenon” under reliability tests. With reference to FIG. 1B, in the multilayer packaging substrate having stacked conductive vias 123, interfaces between the conductive vias 123 are broken due to the high moisture absorption ratio, the mismatch of coefficient of thermal expansion, and too-great elastic modulus of the material of the dielectric layer. Therefore, the quality of the products is decreased by the aforementioned problems. In order to prevent the cracks of the conductive vias 123, the diameters of the upper portions of these conductive vias need to be 60 μm or more. Accordingly, neither the trends toward the conductive vias having smaller diameter can be achieved, nor the packaging substrates having high integration can be manufactured.

### SUMMARY OF THE INVENTION

In view of the above conventional shortcomings, the present invention provides a packaging substrate structure, which comprises at least one circuit layer formed on a surface of a dielectric layer, wherein the circuit layer has a plurality of conductive pads; and a solder mask formed on the surface of the dielectric layer with the circuit layer, and having a plurality of openings to expose the surfaces of the conductive pads of the circuit layer, wherein the solder mask is a dielectric material with Young's Modulus less than 1 GPa and moisture absorption ratio less than 1.0%.

In the packaging substrate structure of the present invention, the material used in the solder mask is a dielectric material with Young's Modulus less than 1 GPa. Preferably, the Young's Modulus of the dielectric material is 50˜800 MPa. More preferably, the Young's Modulus of the dielectric material is 100˜500 MPa. Additionally, the material used in the solder mask is a dielectric material with moisture absorption ratio less than 1.0%. Preferably, the moisture absorption ratio is less than 0.8%. More preferably, the moisture absorption ratio is less than 0.5%.

The packaging substrate structure of the present invention may optionally further comprise a built-up structure formed on another surface of the dielectric layer, and the built-up structure may be a single-layered structure, or a multiple-layered structure. In addition, the built-up structure comprises a built-up circuit layer, and a plurality of conductive vias electrically connected to the built-up circuit layer.

The packaging substrate structure of the present invention mentioned above may further comprise a solder material formed on the surfaces of the conductive pads to electrically connect to an external electronic component. Furthermore, the external electronic component can be selected from a group consisting of a passive component, an active component, a photoelectric component, a semiconductor chip, and a circuit board.

The present invention also provides a packaging substrate structure, which comprises a built-up structure, wherein the built-up structure comprises a dielectric layer, and a circuit layer formed on a surface of the dielectric layer; and an outer dielectric layer formed on the surface of the dielectric layer, and having a plurality of openings to expose the conductive pads. Furthermore, the circuit layer has a plurality of conductive pads. The outer dielectric layer is a dielectric material with Young's Modulus less than 1 GPa and moisture absorption ratio less than 1.0%.

In the packaging substrate structure of the present invention, the material used in the outer dielectric layer is a dielectric material with Young's Modulus less than 1 GPa. Preferably, the Young's Modulus of the dielectric material is 50˜800 MPa. More preferably, the Young's Modulus of the dielectric material is 100˜500 MPa. Additionally, the material used in the outer dielectric layer is a dielectric material with moisture absorption ratio less than 1.0%. Preferably, the moisture absorption ratio is less than 0.8%. More preferably, moisture absorption ratio is less than 0.5%. Hence, the material used in the outer dielectric layer may preferably is a dielectric material with Young's Modulus between 100˜500 MPa and moisture absorption ratio less than 1.0%.

The packaging substrate structure of the present invention mentioned above may further comprise a solder material formed on the surfaces of the conductive pads to electrically connect to an external electronic component. Furthermore, the external electronic component can be selected from a group consisting of a passive component, an active component, a photoelectric component, a semiconductor chip, and a circuit board.

In the packaging substrate structure of the present invention, the built-up structure is a single-layered structure, or a multiple-layered structure. Furthermore, the built-up structure may further comprise at least one inner dielectric layer, a built-up circuit layer laminated on the inner dielectric layer, and a plurality of conductive vias formed in the inner dielectric layer.

When the dielectric material with Young's Modulus less than 1 GPa and moisture absorption ratio less than 1.0% is used in the solder mask, the dielectric material can absorb the stress resulted from the mismatch of coefficient of thermal expansion, reduce this stress, and also protect the packaging substrate structure from the moisture. In addition, when the dielectric material mentioned above is used in the outer dielectric layer, the “popcorn phenomenon” of the manufacturers can be eliminated under the reliability test; and when the layers of the built-up structure are increased, the conductive vias disposed therein do not crack easily. Hence, it is possible to prepare the conductive vias each with a diameter less than 60 μm, and manufacture the packaging substrate structure with high-integration circuits.

Other objects, advantages, and novel features of the invention will become more apparent from the following detailed description when taken in conjunction with the accompanying drawings.

### BRIEF DESCRIPTION OF THE DRAWINGS

FIG. 1A is a cross-sectional view of a conventional packaging substrate structure;

FIG. 1B is an enlargement in a cross-sectional view of the conductive vias shown in FIG. 1A;

FIG. 2 is a cross-sectional view of a packaging substrate structure of a preferred embodiment in the present invention;

FIG. 3 is a cross-sectional view of a packaging substrate structure of another preferred embodiment in the present invention; and

FIG. 4 is a cross-sectional view of a packaging substrate structure of yet another preferred embodiment in the present invention.

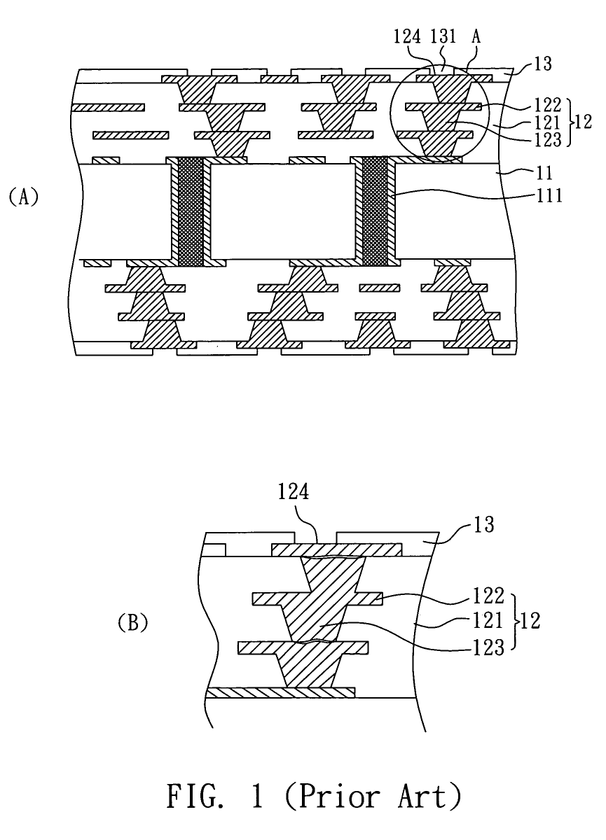

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The drawings of the embodiments in the present invention are all simplified charts or views, and only expose elements relative to the present invention. The elements revealed in the drawings are not necessarily aspects of the practice, and quantity and shape thereof are optionally designed. Further, the design aspect of the elements can be more complex.

### Embodiment 1

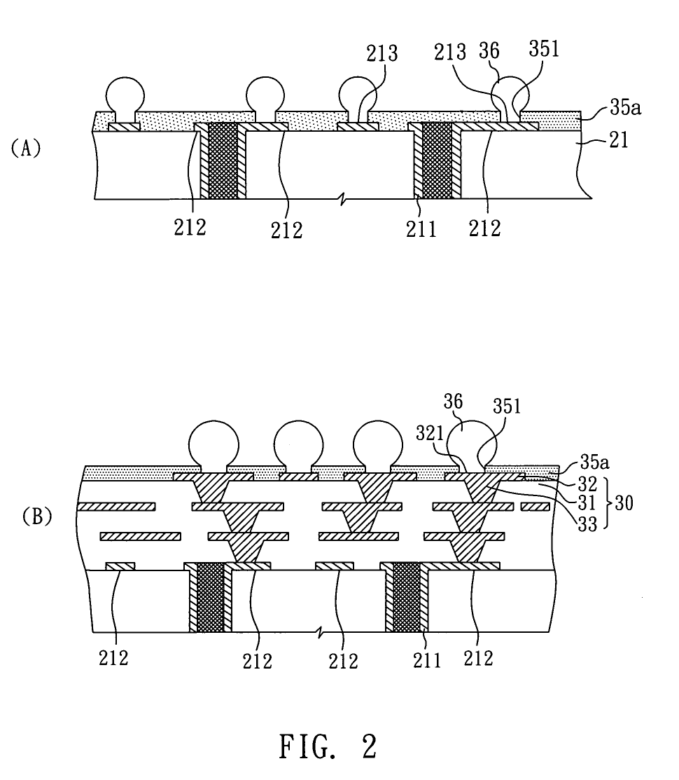

With reference to FIG. 2A, there is shown a packaging substrate structure in the present embodiment, which comprises: a circuit layer 212, and a solder mask 35a. The circuit layer 212 is formed on a surface of a dielectric layer 21, which has a plurality of conductive pads 213. Furthermore, the material used in the dielectric layer 21 is selected from a group consisting of Ajinomoto Build-up film (ABF), bismaleimide triazine (BT), benzocylobutene (BCB), liquid crystal polymer (LCP), polyimide (PI), poly(phenylene ether) (PPE), poly(tetra-fluoroethylene) (PTFE), aramide, epoxy resin and glass fiber. The material of dielectric layer 21 has Young's Modulus at least more than 1 GPa and moisture absorption ratio more than 1.0%. Besides, the packaging substrate structure may also contain plated through holes 211 in the dielectric layer 21, wherein the circuit layers 212 disposed on the two sides dielectric layer 21 may be conducted together by the plated through holes 211. Furthermore, the solder mask 35a is formed on the surface of the dielectric layer 21 with the circuit layer 212 in the present embodiment, and the solder mask 35a has a plurality of openings 351 to expose the surfaces of the conductive pads 213 of the circuit layer 212, wherein the material of the solder mask 35a is a dielectric material with Young's Modulus less than 1 GPa and moisture absorption ratio less than 1.0%.

A solder material 36 may be formed on the surfaces of the conductive pads 213 to electrically connect to an external electronic component. The external electronic component, which is electrically connected to the packaging substrate structure in the present embodiment, may be selected from a group consisting of a passive component, an active component, a photoelectric component, a semiconductor chip, and a circuit board. In the present embodiment, the external electronic component is a semiconductor chip.

With reference to FIG. 2B, a built-up structure 30 may be formed on another surface of the dielectric layer 21 in the present embodiment, wherein a solder mask 35a may be deposited thereon. The solder mask 35a may comprise a plurality of openings 351 to expose a built-up circuit layer 32 as the surfaces of conductive pads 321, wherein the built-up circuit layer 32 is disposed on the surface of the built-up structure 30. In the present embodiment, the built-up structure 30 formed on one side of the dielectric layer 21 is made by built-up technology. Besides, the built-up structure 30 comprises a built-up dielectric layer 31, the built-up circuit layer 32 laminated on the built-up dielectric layer 31, and a plurality of conductive vias 33 which electrically conducts the built-up circuit layer 32 with the inner circuit, and the conductive pads 321 are formed on the surface of the built-up structure 30. Furthermore, the built-up structure 30 may be a single-layered structure, or a multiple-layered structure if it is necessary. In addition, the built-up circuit layer 32 in the built-up structure 30 is electrically conducted to another side of the dielectric layer 21 by a plurality of plated through holes 211.

The material of the built-up dielectric layer 31 may be selected from the same material aforementioned in the dielectric layer 21.

The material used in the solder mask 35a mentioned above may prevent the structure of the packaging substrate against the moisture and also absorb the stress resulted from the mismatch of coefficient of thermal expansion. Hence, the “popcorn phenomenon” can be prevented.

### Embodiment 2

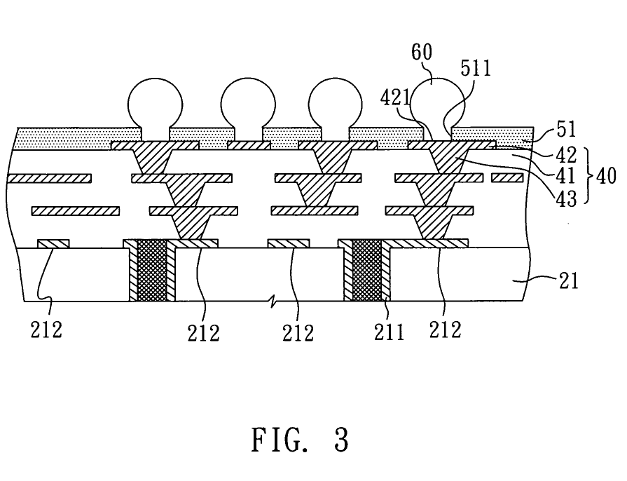

With reference to FIG. 3, there is shown a packaging substrate structure in the present embodiment, which comprises: a built-up structure 40 and an outer dielectric layer 51. The built-up structure 40 comprises a dielectric layer 41, and a circuit layer 42 formed on a surface of the dielectric layer 41, wherein the circuit layer 42 has a plurality of conductive pads 421. The outer dielectric layer 51 is formed on the surface of the dielectric layer 41, and the outer dielectric layer 51 has a plurality of openings 511 to expose the conductive pads 421, wherein the outer dielectric layer 51 is a dielectric material with Young's Modulus less than 1 GPa and moisture absorption ratio less than 1.0%.

Herein, in the packaging substrate structure of the present invention, a solder material 60 is formed on the surface of the conductive pads 421 to electrically connect to an external electronic component (not shown in FIG. 3), which is selected from a group consisting of a passive component, an active component, a photoelectric component, a semiconductor chip, and a circuit board. In the present embodiment, the external electronic component (not shown in FIG. 3) is a semiconductor chip.

The built-up structure 40 of the present embodiment is the same as in embodiment 1. The built-up structure 40 comprises at least one dielectric layer 41 which is an inner dielectric layer, a circuit layer 42 which is a built-up circuit layer laminated on the dielectric layer 41, and a plurality of conductive vias 43 formed in the dielectric layer 41. The difference between the present embodiment and embodiment 1 is that the packaging substrate structure in the present embodiment comprises an outer dielectric layer 51, wherein the material used in the outer dielectric layer 51 is a dielectric material with Young's Modulus less than 1 GPa and moisture absorption ratio less than 1.0%.

The built-up structure 40 in the present invention may be a single-layered structure, or a multiple-layered structure if it is necessary.

The diameters of the upper portions of the conductive vias 43 in the present embodiment may be controlled as being 60 μm or less. Besides, using the packaging substrate structure in the present embodiment may prevent the moisture influencing therein and the stress resulted from the mismatch of coefficient of thermal expansion due to the thermal shock. Hence, it is possible to prevent the electrical quality of the products from being decreased due to the breaks of the conductive vias 43, and the conductive pads 421, or the interface of the circuit layer 42.

### Embodiment 3

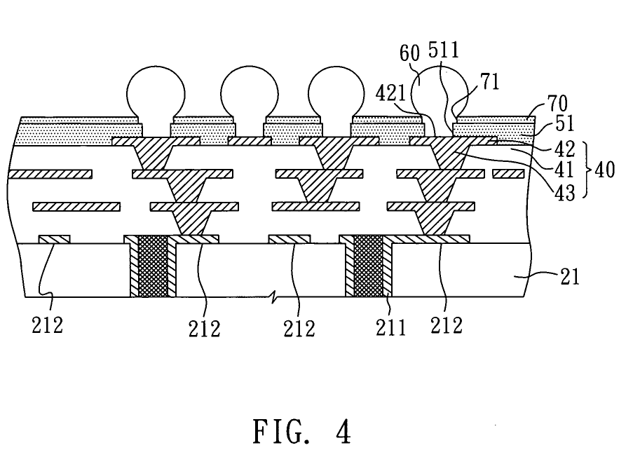

FIG. 4 shows one embodiment of the packaging substrate structure in the present invention, which is almost the same as the packaging substrate structure in embodiment 2. Nevertheless, the difference between the present embodiment and embodiment 2 is that the packaging substrate structure in the present embodiment comprises a solder mask 70 formed on the surface of the dielectric layer in embodiment 2, wherein the solder mask openings 71 correspond to the openings 511 of the outer dielectric layer to expose the conductive pads 421. Furthermore, the solder mask 70 in the present embodiment is a dielectric material with Young's Modulus less than 1 GPa and moisture absorption ratio less than 1.0% to protect the packaging substrate structure from the moisture. Meanwhile, the dielectric material mentioned above also can absorb the stress resulted from the mismatch of the coefficient of thermal expansion and eliminate the “popcorn phenomenon”.

In conclusion, the packaging substrate structure of the present invention comprises a dielectric material with Young's Modulus less than 1 GPa and moisture absorption ratio less than 1.0% in a solder mask, an outer dielectric layer, or the combination thereof. The dielectric material mentioned above can not only protect the packaging substrate structure from the moisture, but also absorb the stress resulted from the mismatch of the coefficient of thermal expansion. Hence, the diameters of the conductive vias may be minimized, and the cracks in the interfaces between the conductive vias and the built-up circuit layers or the conductive pads may also be prevented. Therefore, it is possible to manufacture the packaging substrate structure with high integration.

Although the present invention has been explained in relation to its preferred embodiment, it is to be understood that many other possible modifications and variations can be made without departing from the scope of the invention as hereinafter claimed.

What is claimed is:

1. A packaging substrate structure, comprising:
at least one circuit layer formed on a surface of a dielectric layer, wherein the circuit layer has a plurality of conductive pads; and
a solder mask formed on the surface of the dielectric layer with the circuit layer, and having a plurality of openings to expose the surfaces of the conductive pads of the circuit layer, wherein the solder mask is a dielectric material with Young's Modulus less than 1 GPa and moisture absorption ratio less than 1.0%.

2. The packaging substrate structure as claimed in claim 1, further comprising a built-up structure formed on another surface of the dielectric layer.

3. The packaging substrate structure as claimed in claim 2, wherein the built-up structure is a single-layered structure, or a multiple-layered structure.

4. The packaging substrate structure as claimed in claim 2, wherein the built-up structure comprises a built-up circuit layer, and a plurality of conductive vias connected to the built-up circuit layer.

5. The packaging substrate structure as claimed in claim 1, further comprising a solder material formed on the surfaces of the conductive pads to electrically connect to an external electronic component.

6. The packaging substrate structure as claimed in claim 2, further comprising a solder material formed on the surfaces of the conductive pads to electrically connect to an external electronic component.

7. The packaging substrate structure as claimed in claim 1, wherein the external electronic component is selected from a group consisting of a passive component, an active component, a photoelectric component, a semiconductor chip, and a circuit board.

8. A packaging substrate structure comprising:
a built-up structure, wherein the built-up structure comprises a dielectric layer, and a circuit layer formed on a surface of the dielectric layer, wherein the circuit layer has a plurality of conductive pads; and
an outer dielectric layer formed on the surface of the dielectric layer, and having a plurality of openings to expose the conductive pads, wherein the outer dielectric layer is a dielectric material with Young's Modulus less than 1 GPa and moisture absorption ratio less than 1.0%.

9. The packaging substrate structure as claimed in claim 8, further comprising a solder mask formed on the surface of the outer dielectric layer and having a plurality of solder mask openings, wherein the solder mask openings correspond to the openings of the outer dielectric layer to expose the conductive pads.

10. The packaging substrate structure as claimed in claim 9, wherein the solder mask is a dielectric material with Young's Modulus less than 1 GPa and moisture absorption ratio less than 1.0%.

11. The packaging substrate structure as claimed in claim 9, further comprising a solder material formed on the surfaces of the conductive pads to electrically connect to an external electronic component.

12. The packaging substrate structure as claimed in claim 8, wherein the built-up structure is a single-layered structure, or a multiple-layered structure.

13. The packaging substrate structure as claimed in claim 9, wherein the built-up structure is a single-layered structure, or a multiple-layered structure.

14. The packaging substrate structure as claimed in claim 12, wherein the built-up structure further comprises at least one inner dielectric layer, a built-up circuit layer laminated on the inner dielectric layer, and a plurality of conductive vias formed in the inner dielectric layer.

15. The packaging substrate structure as claimed in claim 10, wherein the external electronic component is selected from a group consisting of a passive component, an active component, a photoelectric component, a semiconductor chip, and a circuit board.
